(19) United States
(12) Patent Application Publication
(10) Pub. No.: US 2016/0066469 A1
(43) Pub. Date: Mar. 3, 2016

(54) COOLING ARRANGEMENT FOR A CIRCUIT PACK

(71) Applicant: Alcatel-Lucent USA Inc., Murray Hill, NJ (US)

(72) Inventors: Todd Richard Salamon, New Providence, NJ (US); Chaonong Yoh, Matawan, NJ (US)

(73) Assignee: Alcatel-Lucent USA Inc., Murray Hill, NJ (US)

(21) Appl. No.: 14/472,684

(22) Filed: Aug. 29, 2014

(51) Int. Cl. H05K 7/20

(52) U.S. Cl. CPC H05K 7/20154; H05K 7/20145; H05K 7/20181

(57) ABSTRACT

A circuit structure comprises a circuit board. An array of opto-electronic devices is provided on the circuit board. At least some of heat sinks are provided in thermal contact with a respective opto-electronic device. A face plate of the circuit structure comprises an array of openings configured to allow air to move along a path adjacent to an opto-electronic device and through a respective heat sink. An air moving device is located adjacent a heat sink and is operable to drive air through a respective opening on the face plate. A ducting structure is provided to direct the air driven by a corresponding air moving device.

### TECHNICAL FIELD

The present invention is directed, in general, to a cooling solutions for circuit packs.

### BACKGROUND

Opto-electronic devices such as Small Form Factor Pluggables (SFPs), 10 Gigabit Small Form Factor Pluggables (XFPs), C-Form Factor Pluggables (CFPs), and the like, contain lasers that typically have stringent thermal requirements. These devices are typically placed on circuit packs within a shelf in a location that is adjacent to the circuit pack face plate, so as to allow the connection of optical fibers to the devices.

There is a need to add bandwidth capacity and functionality to telecommunications and data networking products so as to satisfy growing customer demand. For this reason there is a preference to populate as much as possible the face plate of a circuit pack with as many opto-electronic devices as the face plate and circuit pack are able to accommodate. In such a configuration a linear array of opto-electronic devices is often arranged along the length of the circuit pack and attached to the face plate.

### SUMMARY

Some embodiments feature a circuit structure comprising:
a circuit board;
an array of opto-electronic devices;
an array of heat sinks, at least some of the heat sinks from the array of heat sinks being in thermal contact with a respective opto-electronic device; and a face plate configured to allow optical connection from an external device to one or more opto-electronic devices;

wherein the circuit structure further comprises:
one or more openings, located on the face plate wherein at least one opening is configured to allow air to move along a path adjacent to an opto-electronic device and through a respective heat sink;
an air moving device located adjacent a heat sink configured to drive air through a respective opening;
a ducting structure configured to direct the air driven by an air moving device.

According to some specific embodiments an opto-electronic device, a heat sink, a ducting structure and an air moving device are included in an integrated single structure.

According to some specific embodiments an air filtering element is located in a flow path of air driven by the air moving device to filter particulates floating in the driven air.

According to some specific embodiments an air filtering element is comprised in the integrated single structure and located in a flow path of air driven by the air moving device to filter particulates floating in the driven air.

According to some specific embodiments an opto-electronic device from the array of opto-electronic devices is placed inside of a hollow metallic structure.

According to some specific embodiments an opto-electronic device from the array of opto-electronic devices is placed inside of a hollow metallic structure and the hollow metallic structure is comprised in the integrated single structure.

According to some specific embodiments a heat transfer interface, made from a thermally conductive material, is provided between the opto-electronic device and the heat sink.

According to some specific embodiments a heat transfer interface, made from a thermally conductive material, is provided between the hollow metallic structure and the heat sink.

According to some specific embodiments at least some of the opto-electronic devices from the array of opto-electronic devices are arranged according to a planar pattern such that the opto-electronic devices are located in the same layer with respect to each other over the surface of the circuit board.

According to some specific embodiments at least one of the opto-electronic devices from the array of opto-electronic devices is stacked upon another one of the opto-electronic devices from the array of opto-electronic devices.

According to some specific embodiments the ducting structure further comprises a conduit for air from a heat sink to an air outlet of the circuit structure.

According to some specific embodiments the heat sink has a structure comprising parallel planar fins, said parallel planar fins forming at least a part of the ducting structure.

According to some specific embodiments the circuit structure is configured to receive ambient air from an air inlet and let out received air through an air outlet, and a blocking structure is located upstream of a row of opto-electronic devices, relative to the flow of air from the air inlet to the air out, and is configured to direct said air received through the air inlet away from the opto-electronic devices.

According to some specific embodiments an air moving device is associated with more than one heat sink.

According to some specific embodiments an air moving device is associated with more than one ducting structure.

According to some specific embodiments the air moving device is a piezoelectric fan or a micro-blower.

According to some specific embodiments the opto-electronic device is an opto-electronic device.

According to some specific embodiments the opto-electronic device is a Small Form Factor Pluggable device, a 10 Gigabit Small Form Factor Pluggable device, or a C-Form Factor Pluggable device.

According to some specific embodiments the circuit structure comprises an opto-electronic device with a heat load, such heat load having a value comprised in the range of about 1 W to about 100 W.

According to some specific embodiments the opto-electronic device has a heat load having a value comprised in the range of about 10 W to about 30 W.

### BRIEF DESCRIPTION OF THE DRAWINGS

For a more complete understanding of the present disclosure, reference is now made to the following description taken in conjunction with the accompanying drawings, in which:

FIGS. 1a, 1b and 1c are respectively exemplary schematic representations of a top view, a front view and a side view of a known circuit pack.

FIGS. 2a, 2b and 2c are respectively exemplary schematic representations of a top view, a front view and a side view of a circuit pack according to some embodiments of the disclosure.

### DETAILED DESCRIPTION OF ILLUSTRATIVE EMBODIMENTS

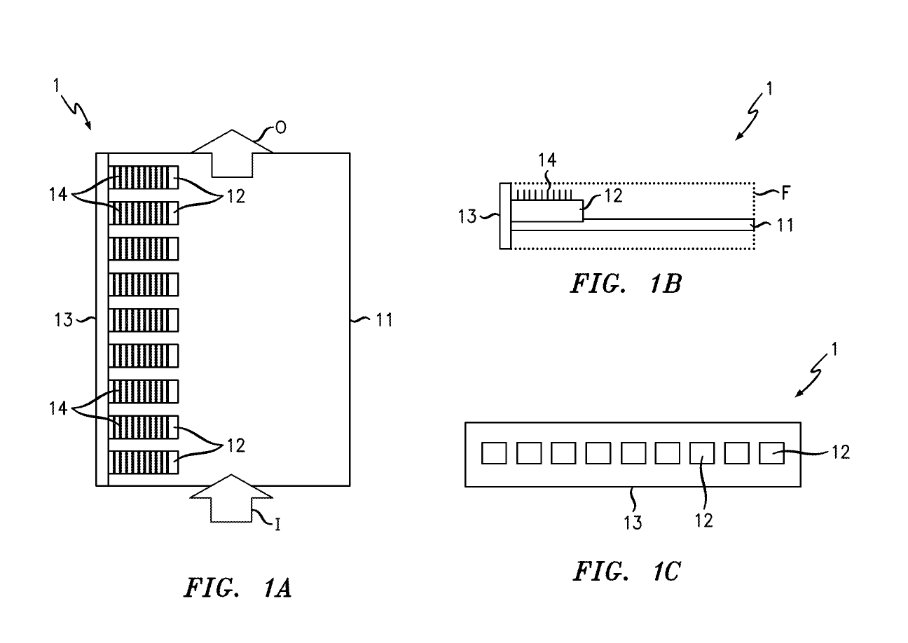

With simultaneous reference to FIGS. 1a, 1b and 1c, a circuit pack 1 structured according to known designs is shown. The circuit pack 1 comprises a circuit board 11, an array of opto-electronic devices 12 and a face plate 13. The opto-electronic devices may be, but not limited to, SFPs, XFPs, CFPs or the like. Typically each opto-electronic device 12 is attached to a heat sink 14 which is in charge of dissipating the heat generated by the opto-electronic device during operation.

As it is more clearly shown in FIG. 1a, the opto-electronic devices 12 are aligned along, and proximate to, the face plate 13.

There are several technical problems associated with this design.

One such problem is that the typical pitch between adjacent circuit packs, when installed within a shelf, is often provided such that little room is left available for placing a heat sink to transfer heat from the opto-electronic device to the air flowing across the circuit pack. The dashed line F in FIG. 1b schematically represents the form factor within which the devices on the circuit pack must remain in order to accommodate the pitch within a shelf.

Due to this limited available space, heat sinks for use in these circuit packs are designed with relatively short heights. For example some typical heat sinks have fin heights of only about 1 or 2 mm. As it is known, shorter heat sinks provide poorer heat transfer as compared to longer heat sinks. Therefore, the heat transfer performance of such known circuit packs is often not optimum.

A second problem is that the direction of air flow across a circuit pack for cooling the opto-electronic devices is such that air typically enters the circuit pack at one end of the linear array of opto-electronic devices, and exits the circuit pack at the opposite end of the linear array. Referring to FIG. 1a, the inlet air is represented by arrow I and the outlet air is represented by arrow O. This arrangement however is problematic as the air becomes progressively heated as it flows over the opto-electronic devices in the linear array, such that the opto-electronic devices closest to the downstream end of the circuit pack (e.g. the devices shown at the upper part of FIG. 1a) receive significantly warmer air compared to those near the upstream end of the circuit pack (e.g. the devices shown at the lower part of FIG. 1a), thus making it extremely challenging to cool these devices.

Another drawback associated with the known design of circuit packs is that the opto-electronic devices are often placed inside of a hollow metallic structure, also referred to as a cage (not specifically shown), which provides some electromagnetic shielding for the device and also allows the device to attach to electrical leads that connect to the circuit board. The thermal contact between the outer surface of the opto-electronic device and the inner surface of the cage is typically quite poor, as it is usually a metal-to-metal contact with no intervening thermal interface material such as thermal grease. This poor thermal contact therefore gives rise to additional thermal resistance in the transfer of heat from the opto-electronic device to the cage. Similar issues may exist between the cage and a heat sink attached to the cage, thereby also presenting poor thermal contact between the latter two structures.

Several solutions may be thought of in order to address the above drawbacks.

One approach may be based on increasing the pitch of the circuit packs thus allowing the use of taller heat sinks and a greater space for air flow. However, this approach has a drawback as it reduces the number of circuit pack slots that a shelf can accommodate, thereby reducing the potential bandwidth capacity and functionality of a shelf.

Another approach may be based on driving more air flow across the circuit pack to provide sufficient cooling of the devices. However, driving more air would require the use of higher throughput capacity fans and/or blowers which typically demand greater power, run at higher speeds/rpm, and have increased acoustic noise emissions that can cause a product to fail established acoustic noise requirements such as those of NEBS and ETSI.

It is therefore desired to provide a solution which eliminates or substantially reduces the above drawbacks.

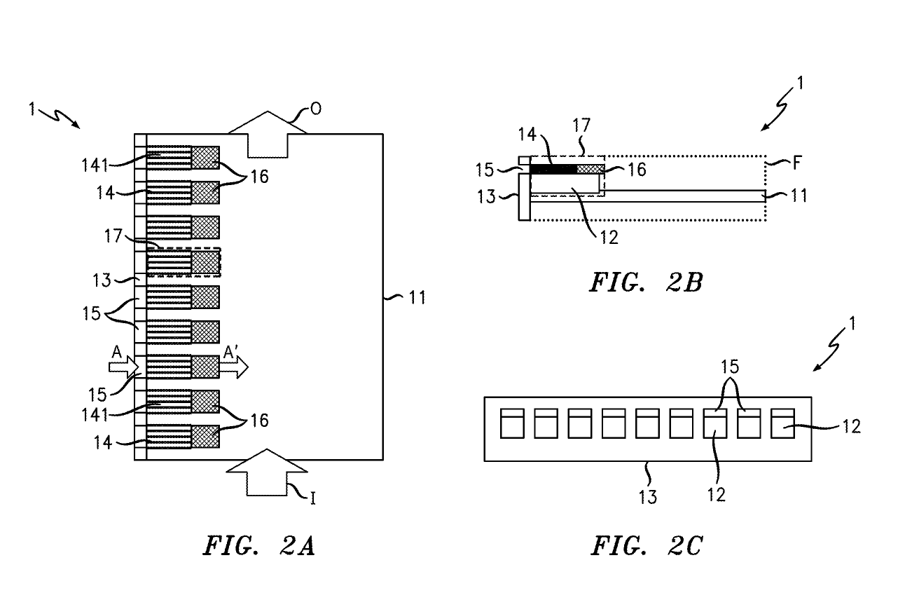

FIGS. 2a, 2b and 2c are respectively exemplary schematic representations of a top view, a front view and a side view of a circuit pack according to some embodiments of the disclosure. In these figures like elements have been provided with like reference numerals as those of FIGS. 1a, 1b and 1c.

With simultaneous reference to FIGS. 2a, 2b and 2c, there is illustrated a circuit pack 1 comprising a circuit board 11, an array of opto-electronic devices 12 and a face plate 13. Here again, the opto-electronic devices may be any opto-electronic devices such as, but not limited to, SFPs, XFPs, CFPs or the like. Preferably each opto-electronic module 12 is attached to a heat sink 14 which is in charge of dissipating the heat generated by the opto-electronic device during operation.

As it is more clearly shown in FIG. 2a, the opto-electronic modules 12 are aligned along, and proximate to, the face plate 13. However this is not the only configuration possible and the opto-electornic devices may also be located at other convenient locations on the circuit board as will be described further below.

The opto-electronic devices 12 may be placed inside a hollow metallic structure, also referred to as a cage (not specifically shown), which provides some electromagnetic shielding for the device and also allows the device to attach to electrical leads that connect to the circuit board.

According to embodiments of the disclosure, the circuit pack 1 is provided with openings that allow cool air to be pulled from the exterior space in front of the circuit pack face plate 13 and across the opto-electronic device. This is schematically shown in FIGS. 2a, 2b and 2c, where openings 15 are provided on the structure of the face plate 13. Each individual opening 15 extends from the face plate 13 toward the inside of the circuit pack 1 defining a path that passes above the opto-electronic device 12 (with or without the cage), through the structure of the heat sink 14 to provide a passage of air from front side of the circuit pack 1, i.e. external ambient air in the vicinity of the face plate 13, to the interior of the shelf as shown by arrow A-A′ in FIG. 2a.

As it can be appreciated from FIG. 2a, the direction of passage of air through the openings 15 (arrow A-A′) provides an additional flow of air to cool the opto-electronic devices 12 individually. Therefore, with this arrangement, cool air is caused to flow inside the shelf and over individual opto-electronic devices without the disadvantage of the known solutions in which warmer air is provided to the devices located closest to the downstream end of the circuit pack, as described with reference to FIG. 1a.

In order to further improve the cooling performance of the circuit pack, an air moving device 16, such as a piezoelectric fan, piezoelectric blower a rotating blower or a microblower (i.e. a blower based on rotary components, similar to a conventional rotary fan as widely used, however made at comparatively a much smaller size), or any other similar device, is placed adjacent the heat sink 14 or the opto-electronic device (and metallic cage, if available) in order to provide a driving force for air movement. Preferably the air moving device 16 is located over (on top of) of the opto-electronic device. The air moving device 16 therefore contributes to a more efficient flow of air, through the opening 15, from the front side of the circuit pack 1 to the interior of the shelf as shown by arrow A-A′.

The air moving device 16 may be selected with an air flow strength which is suitable for the circuit pack design in which it will be incorporated. Some examples are air moving devices capable of generating air flow with a corresponding pressure head of between 0 and 100 Pa, or from 0 to 300 Pa, or from 0 to 500 Pa, or from 0 to 1000 Pa. This is to ensure inflow of air from the external ambient, through the opto-electronic device, and onto the circuit pack, which itself may be pressurized relative to ambient.

As more clearly shown in FIG. 2b, the heat sink 14 may be placed atop the opto-electronic device 12 (or metallic cage, if available) in order to transfer heat from the opto-electronic device (or metallic cage, if available) to the cool air that is being driven by the air moving device 16.

In the embodiment of FIGS. 2a, 2b and 2c, the air moving device 16 is shown to be located downstream the heat sink 14 relative to the direction of flow of the air A-A′. However, this is only exemplary and the disclosure is not so limited. For example, the air moving device 16 may be located upstream the heat sink 14 relative to the direction of flow of the air A-A′.

Likewise, more than one air moving device may be used for cooling an opto-electronic device 12. This may be the case where larger size opto-electronic devices, e.g. devices used for high power applications, are present in the shelf thus requiring a stronger air flow for their cooling.

To further improve heat transfer between the opto-electronic device (or metallic cage, if available) and the corresponding heat sink, a heat transfer interface may be used, such as a thermally conductive adhesive or grease, or a thin and deformable metal interface (not shown).

For the sake of clarity with respect to the use of the term heat transfer characteristics, or said in other words, thermal conductivity, as used herein, the following clarification is provided. As it is known, many materials, and even from a pure theoretical standpoint any material, may be considered to be thermally conductive (thus having heat transfer capabilities) as each material has a certain level of thermal conductivity, even if in some cases such level is very low. However, within the context of the present disclosure, a person of ordinary skill in the related art would be able to distinguish a material which is considered in the art as thermally conductive from one which is not so considered, such as for example a thermal insulator.

By way of still further clarification, it is noted that within the context of the present disclosure, any material having a thermal conductivity equal or greater than about 1 W/mK (Watts per Meter Kelvin) may be considered as a thermally conductive material. Conversely, any material having a thermal conductivity of less than about 1 W/mK may be considered as thermally non-conductive. Within the thermal conductivity range described above, a thermal conductivity greater than 100 W/mK may be considered as a high thermal conductivity value and one within the range of 1-100 W/mK may be considered as an acceptable value.

It is however to be noted that in addition to the thermal conductivity, other factors may also affect the heat transfer response of the heat transfer interface. Thickness is one of such factors. For example in some cases, a very thin heat transfer interface, although made of a relatively poor thermal conductivity material, may be capable of transferring heat in a more efficient manner than a thick heat transfer structure made of a material with comparatively good thermal conductivity. Another factor may be the interfacial contact resistances between the heat transfer interface and the two surfaces it is in contact with.

A further improvement in cooling may be obtained by using a ducting structure. Such ducting structure may be formed by fins, or any form of conduit, for example having planar walls, provided in the heat sink structurs 14 as shown by reference numeral 141. Such ducting structure 141 may help to ensure that the cool air taken from the front space of the circuit pack 1 passes through the heat sink 14 and the air moving device 16, and then exits into the air space within the interior of the circuit pack 1. This approach is of particular advantage as it allows the cooling of each individual opto-electronic device to be decoupled from (or substantially unaffected by) the cooling of adjacent opto-electronic devices, as each opto-electronic device 12 receives its corresponding supply of fresh air from the front of the circuit pack 1. The approach also decouples the cooling from other electronic components on the circuit pack

Furthermore, opto-electronic devices may be arranged according to a planar pattern such that the devices are located in the same layer with respect to each other over the surface of the circuit board 11, or they may be stacked upon each other (i.e. one on top of the other). In this arrangement separate openings may be provided in the face plate for each layer of opto-electronic devices along with corresponding separate metallic cages, ducts, heat sinks and air moving devices.

Additional ducting structure may also be provided in the circuit pack in the form of any convenient conduit for air (not specifically shown in the figures) from the heat sinks 14 and air moving devices 16 to the air outlet O. This option may serve to isolate the heated air, after flowing over an opto-electronic device, from flowing adjacent to other opto-electronic devices or other components of the circuit board.

It is further noted that the proposed arrangement for the ducting structure is also consistent with telecommunications specifications for air flow, where the air is required to enter the equipment from the front of the shelf, and then exit either out the back of the shelf, or at the top of the shelf. In some known arrangements, a plenum is attached to the bottom of an inlet to the circuit pack to pull the air from the front of the shelf. The present solution obviates the need for a specific plenum (although it does not exclude such possibility) as the air can be drawn directly through the ducting structure.

As a still further improvement measure, an air filter element may optionally be placed in the air flow path (e.g. arrows A-A′) defined by the ducting structure 141, for example, in the opening within the circuit pack face plate, to filter out any particulates floating in the air to prevent them from entering into the space within the circuit pack. The air filter may be part of the shelf front door, which would simplify the air filter maintenance or replacement. The provision of an air filter to block particulates may be advantageous as it helps to protect the electronics within the shelf and also to reduce the adherence of dust and dirt to the air moving device 16, which is otherwise detrimental to the optimum operation of the air moving device, thus contributing to an improved cooling performance.

A yet further improvement measure relates to providing a single structure comprising a number of components of the circuit pack such that the single structure can be removed from the circuit pack by sliding the structure out of the circuit pack face plate in the form of a plug-and-play capability. Therefore, differently from the arrangement of known circuit packs such as the example shown in FIGS. 1a, 1b and 1c, in which discrete and independent components (e.g. opto-electronic device, heat sink, etc) are installed on the circuit board, the present solution proposes the use of an integrated device that incorporates at least some of the components into a single module. As a non-limiting example, some or all of the following components may be integrated into a single structure: the opto-electronic device 12, the metallic cage (if used), the heat sink 14, the ducting structure 141, the air moving device 16 and the air filtering element. The integrated single structure is represented in FIGS. 2a and 2b by a dashed rectangle 17.

After certain period of prolonged operation, the components may age and/or dust and dirt may degrade their optimum operation (for example, that of the air moving device). As a result of such degradation, the cooling process may become inefficient and result in overheating of the opto-electronic devices 12. The aforementioned plug-and-play capability of the integrated single structure 17 provides the possibility of a fast and simple repair, replacement or upgrade when needed.

To ensure efficient heat transfer between the heat sink and the opto-electronic device 12, the heat sink 14 may be directly integrated into the package of the opto-electronic device 12. Alternatively, a low thermal resistance (i.e. highly thermally conductive) thermal interface material may be used to connect the heat sink to the opto-electronic device. This approach provides a major improvement over current known circuit packs, where metal-to-metal contact is provided between the opto-electronic device and heat sink and gap between irregularities of their respective surfaces is typically filled with air. In particular, the current known solutions often have about 30%-40% of the overall thermal resistance between the device case and the ambient air being associated with the metal-to-metal contact with intervening air gap interface. Therefore the provision of an efficient heat transfer between the opto-electronic device and the heat sink as described above contributes to reducing thermal resistance.

In this manner, a solution is provided that allows cool air to be provided for cooling of the opto-electronic device, irrespective of the location of the latter on a circuit pack, and thus solves a pressing and challenging problem in the thermal management of opto-electronic devices.

Optionally, the above mentioned components may be integrated in a single structure with the exception of the opto-electronic device. This option would provide the possibility of easy removal, in case of need, of the opto-electronic device from the metallic cage when the circuit pack is installed in the shelf. The metallic cage, heat sink, duct and air moving device are semi-permanently attached to the circuit pack and can only be removed after the circuit pack is removed from a shelf.

In order to provide power to the air moving device, an electrical connection may be provided between either the air moving device and the opto-electronic device or the air moving device and the circuit board.

The heat sink may have a structure comprising parallel planar fins or pin fins, or any other convenient structure. In case parallel planar fins are present in the heat sink, they can be used at least as a part of a ducting structure. Conversely, if are not parallel planar fins present in the heat sink, or in case the heat sink has other structures, then appropriate air ducting may be provided through the heat sink and above the opto-electronic device by providing specific structures for that purpose.

Optionally, a blocking structure may be placed upstream of the row of opto-electronic devices to direct the inlet air that normally passes over the circuit pack, and which is driven by fans in a fan tray, away from the opto-electronic devices so that this air primarily flows over other components on the circuit pack, and does not pass over the opto-electronic devices.

Optionally, an air moving device may be associated to more than one heat sink and/or more than one ducting structure and/or more than one opto-electronic device. In such case, one air moving device may operate to drive air for cooling more than one opto-electronic device.

Although the various components described herein, such as the opto-electronic device, the metallic cage, the heat sink, the ducting structure, the air moving device and the air filtering element, have been represented in the figures or described in the present description at specific locations and/or according to specific arrangements, the disclosure is not so limited and other locations and/or arrangements may equally be provided for these components within the scope of the invention as expressed in the following claims.

The present disclosure therefore provides a scalable solution to increasing opto-electronic device densities on circuit packs while continuing to use air cooling.

It is to be noted that the use of piezoelectric fans as air moving devices is preferable as it may eliminate the need to use conventional rotary fans which typically consume higher power than piezoelectric fans and run at higher RPM, which generates increased acoustic noise.

Thanks to the solution proposed herein, the circuit pack pitch does not need to be increased to accommodate increasing opto-electronic device densities. Hence, the equipment density and functionality does not need to be compromised.

The invention disclosed herein covers a broad scope of applicability, and without limitation, the invention is particularly relevant for use with opto-electronic devices with heat loads in the range of about 1 W to about 100 W and in particular in the range of about 10 W to about 30 W.

While this disclosure includes references to illustrative embodiments, this specification is not intended to be construed in a limiting sense. Various modifications of the described embodiments, as well as other embodiments within the scope of the disclosure, which are apparent to persons skilled in the art to which the disclosure pertains are deemed to lie within the principle and scope of the disclosure, e.g., as expressed in the following claims.

Unless explicitly stated otherwise, each numerical value and range should be interpreted as being approximate as if the word “about” or “approximately” preceded the value of the value or range.

It will be further understood that various changes in the details, materials, and arrangements of the parts which have been described and illustrated in order to explain the nature of this invention may be made by those skilled in the art without departing from the scope of the invention as expressed in the following claims.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments.

It should be appreciated by those of ordinary skill in the art that any block diagrams herein represent conceptual views of illustrative circuitry embodying the principles of the invention.

What is claimed is:

1. A circuit structure comprising:
a circuit board;
an array of opto-electronic devices;
an array of heat sinks, at least some of the heat sinks from the array of heat sinks being in thermal contact with a respective opto-electronic device; and
a face plate configured to allow optical connection from an external device to one or more opto-electronic devices;
wherein the circuit structure further comprises:
one or more openings, located on the face plate wherein at least one opening is configured to allow air to move along a path adjacent to an opto-electronic device and through a respective heat sink;
an air moving device located adjacent a heat sink configured to drive air through a respective opening;
a ducting structure configured to direct the air driven by an air moving device.

2. The circuit structure of claim 1, wherein an opto-electronic device, a heat sink, a ducting structure and an air moving device are included in an integrated single structure.

3. The circuit structure of claim 1, wherein an air filtering element is located in a flow path of air driven by the air moving device to filter particulates floating in the driven air.

4. The circuit structure of claim 2, wherein an air filtering element is comprised in the integrated single structure and located in a flow path of air driven by the air moving device to filter particulates floating in the driven air.

5. The circuit structure of claim 1, wherein an opto-electronic device from the array of opto-electronic devices is placed inside of a hollow metallic structure.

6. The circuit structure of claim 2, wherein an opto-electronic device from the array of opto-electronic devices is placed inside of a hollow metallic structure and the hollow metallic structure is comprised in the integrated single structure.

7. The circuit structure of claim 1, wherein a heat transfer interface, made from a thermally conductive material, is provided between the opto-electronic device and the heat sink.

8. The circuit structure of claim 1, wherein a heat transfer interface, made from a thermally conductive material, is provided between the hollow metallic structure and the heat sink.

9. The circuit structure of claim 1, wherein at least some of the opto-electronic devices from the array of opto-electronic devices are arranged according to a planar pattern such that the opto-electronic devices are located in the same layer with respect to each other over the surface of the circuit board.

10. The circuit structure of claim 1, wherein at least one of the opto-electronic devices from the array of opto-electronic devices is stacked upon another one of the opto-electronic devices from the array of opto-electronic devices.

11. The circuit structure of claim 1, wherein the ducting structure further comprises a conduit for air from a heat sink to an air outlet of the circuit structure.

12. The circuit structure of claim 1, wherein the heat sink has a structure comprising parallel planar fins, said parallel planar fins forming at least a part of the ducting structure.

13. The circuit structure of claim 1, wherein the circuit structure is configured to receive ambient air from an air inlet and let out received air through an air outlet, and a blocking structure is located upstream of a row of opto-electronic devices, relative to the flow of air from the air inlet to the air outlet, and is configured to direct said air received through the air inlet away from the opto-electronic devices.

14. The circuit structure of claim 1, wherein an air moving device is associated with more than one heat sink.

15. The circuit structure of claim 1, wherein an air moving device is associated with more than one ducting structure.

16. The circuit structure of claim 1, wherein the air moving device is a piezoelectric fan or a micro-blower.

17. The circuit structure of claim 1, wherein the opto-electronic device is a Small Form Factor Pluggable device, a 10 Gigabit Small Form Factor Pluggable device, or a C-Form Factor Pluggable device.

18. The circuit structure of claim 1 comprising an opto-electronic device with a heat load, such heat load having a value comprised in the range of about 1 W to about 100 W.

19. The circuit structure of claim 18 wherein the opto-electronic device has a heat load having a value comprised in the range of about 10 W to about 30 W.
